(19) United States
(12) Patent Application Publication
(10) Pub. No.: US 2026/0219306 A1
(43) Pub. Date: Jul. 30, 2026

(54) Configuration method based on multipole method

(71) Applicant: XPEEDIC CO., LTD., Shanghai (CN)

(72) Inventors: Liguo JIANG, Shanghai (CN); Wenliang DAI, Shanghai (CN); Mingyu Wang, Shanghai (CN); Ping LIU, Shanghai (CN); Jimin Wen, Shanghai (CN)

(73) Assignee: XPEEDIC CO., LTD., Shanghai (CN)

(21) Appl. No.: 19/143,569

(22) PCT Filed: Dec. 26, 2023
(86) PCT No.: PCT/CN2023/141782

§ 371 Date: Jun. 26, 2025

(30) Foreign Application Priority Data
Apr. 27, 2023 (CN) 202310474120.4

(51) Int. Cl. G01R 27/26; G06F 17/16

(52) U.S. Cl. CPC G01R 27/2611; G06F 17/16

(57) ABSTRACT

The invention provides a method for extracting and configuring resistance and inductance (RL) parameters based on a fast multipole method, which comprises following steps: proposing brand-new basis functions, dividing surface currents using centroid-midpoint basis functions, configuring an accurate impedance model, and proposing a brand-new method and preconditions for using FMM; the CM basis function introduced by the present invention can convert traditional vector bit integration operations based on edges into scalar bit integration operations based on surface elements, and the new integration calculation method is easier to operate and faster in calculation speed. The accurate impedance model enables the present invention to carry out broadband simulation from low frequency to high frequency; the corresponding use of FMM only needs to be based on the surface elements of edges. It is easier to configure the fast multipole method.

### TECHNICAL FIELD

The present invention relates to the field of algorithm optimization for parasitic parameter extraction, and in particular to a configuration method for RL (resistance-inductance) parameter extraction based on a multipole method.

### BACKGROUND TECHNOLOGY

Existing algorithms for solving impedance parameters based on surface integral equations require calculating surface current distribution on conductors. To discretize the surface current, the prior art employs RWG (Rao-Wilton-Glisson) basis functions. RWG basis functions are defined on edges of each surface element. Computation of vector potential integrals involving RWG basis functions is relatively complex. Furthermore, when used in conjunction with a fast multipole method, the RWG currents need to be decomposed into x, y, and z components for invocation. It is time-consuming and difficult to calculate and configure. Filling of edge-based preconditioner matrices is also relatively time-consuming.

### SUMMARY OF INVENTION

Based on the foregoing problems, the present invention is proposed to provide a configuration method based on a multipole method that overcomes the above-mentioned problems or at least partially addresses them.

According to one aspect of the present invention, a configuration method based on the fast multipole method is provided, the configuration method comprising:
meshing a surface of a conductor into hybrid rectangular/triangular surface elements, wherein number of the elements is Nₚ, number of edges is Nₑ, and number of loop currents is N₁;
establishing a sparse mapping matrix M from the loop currents to the edges;
establishing sparse mapping matrices A₁, A₂, A₃ from the edges to the surface elements;
discretizing conductor surface current using centroid-midpoint basis functions first proposed herein;
applying the sparse mapping matrices to map the loop currents onto the surface elements;
constructing a preconditioner matrix;
accelerating matrix-vector multiplication by configuring the fast multipole method based on the surface elements; and
post-processing to extract RL ((resistance-inductance) parameters.

Optionally, the sparse mapping matrix M has dimensions N₁×Nₑ, and the sparse mapping matrices A₁, A₂, A₃ each have dimensions Nₑ×Nₚ.

Optionally, a non-zero element of the matrix M is 1 or −1, wherein the element is set to 1 if directions of currents defined on associated edges align with directions of the loop currents, and is set to −1 if the directions are opposite.

Optionally, the non-zero element in each column of the sparse mapping matrices A₁, A₂, A₃ corresponds to indices of edges belonging to associated surface elements; values of the matrices are respectively x-, y-, or z-components of difference vectors between midpoint coordinates of the edges and centroid coordinates of the surface elements.

Optionally, a method for obtaining the sparse mapping matrices A₁, A₂, A₃ specifically comprises:
for surface element Sᵢ, obtaining current vectors ρᵢₖ associated with each of the edges; and for surface element Sⱼ, obtaining current vectors ρⱼ₁ associated with each of the edges;
k and 1 are indices of the edges on the surface elements Sᵢ and Sⱼ, respectively;
if directions of the current vectors ρᵢₖ align with current directions defined on the associated edges, then: A₁(k, i)=ρᵢₖ(x), A₂(k, i)=ρᵢₖ(y), and A₃(k, i)=ρᵢₖ(z); otherwise: A₁(k, i)=−ρᵢₖ(x), A₂(k, i)=−ρᵢₖ(y), and A₃(k, i)=−ρᵢₖ(z); wherein x, y, z denote the x-, y-, and z-components of the current vectors; and
if directions of the current vectors ρⱼ₁ align with the current directions defined on the associated edges, then: A₁(1, j)=ρⱼ₁(x), A₂(1, j)=ρⱼ₁(y), and A₃(1, j)=ρⱼ₁(z); otherwise: A₁(1, j)=−ρⱼ₁(x), A₂(1, j)=−ρⱼ₁(y), and A₃(1, j)=−ρⱼ₁(z).

Optionally, based on mapping the loop currents onto the surface elements, a formulation is as follows:
a linear equation for solving the RL parameters by using loop current analysis is further transformed into:

$${Z}_{S} {I}_{l} + M ( {A}_{1} {PA}_{1}^{T} + {A}_{2} {PA}_{2}^{T} + {A}_{3} {PA}_{3}^{T} ) {M}^{T} {I}_{l} = {V}_{l} ;$$

wherein, P denotes a surface element-based scalar potential integral matrix;
M(A₁PIₚ₁+A₂PIₚ₂+A₃PIₚ₃)=V₁; and
wherein,

$${I}_{p 1} = {A}_{1}^{T} {M}^{T} {I}_{l} , {I}_{p 2} = {A}_{2}^{T} {M}^{T} {I}_{l} , {I}_{p 3} = {A}_{3}^{T} {M}^{T} {I}_{l} .$$

The present invention provides a configuration method for RL parameter extraction based on the multipole method, comprising converting vector potential integral computations involving RWG basis functions into scalar potential integral calculations via impulse functions. Since the impulse functions are defined on the surface elements, the new integral calculation approach is more operable and delivers substantially accelerated computation speeds. Consequently, when applying the fast multipole method, operations only need to be configured based on the surface elements instead of the edges, so it is easier to configure the fast multipole method.

The above description is only an overview of technical solutions of the present invention. In order to more clearly understand technical means of the present invention, it can be implemented according to the contents of the specification. In order to make the above and other purposes, features and advantages of the present invention more obvious and easy to understand, the specific embodiments of the present invention are listed below.

### DESCRIPTION OF DRAWINGS

In order to more clearly illustrate the technical solutions of the embodiments of the present invention, the attached drawings required for use in the description of the embodiments will be briefly introduced below. Obviously, the attached drawings described below are only some embodiments of the present invention. For those of ordinary skill in the art, other attached drawings can be obtained based on these attached drawings without paying creative work.

FIG. 1 is a flow chart of a configuration method for RL parameter extraction based on a multipole method provided in an embodiment of the present invention;

FIG. 2 is a schematic diagram of arrow indications of a sparse mapping matrix provided by an embodiment of the present invention;

FIG. 3 is a schematic diagram of an algorithm for generating three mapping matrices provided by an embodiment of the present invention.

### EMBODIMENTS

The exemplary embodiments of the present disclosure will be described in more detail below with reference to the attached drawings. Although the exemplary embodiments of the present disclosure are shown in the attached drawings, it should be understood that the present disclosure can be implemented in various forms and should not be limited by the embodiments set forth herein. On the contrary, these embodiments are provided to enable a more thorough understanding of the present disclosure and to fully convey the protective scope of the present disclosure to those skilled in the art.

The terms “comprises” and “having” and any variations thereof in the description embodiments, claims and drawings of the present invention are intended to cover non-exclusive inclusions, for example, comprising a series of steps or units.

In the following, the technical solutions of the present invention will be further described in detail with the attached drawings and embodiments.

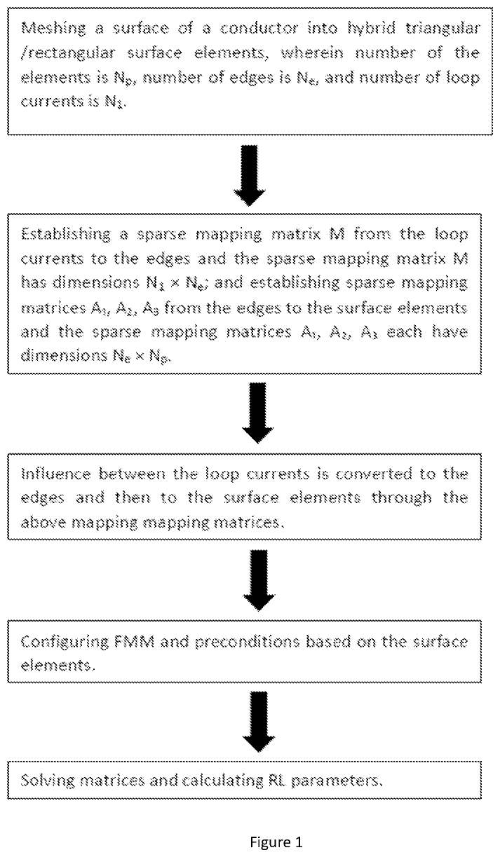

As shown in FIG. 1, meshing a surface of a conductor into hybrid rectangular/triangular surface elements, wherein number of the surface elements is Nₚ, number of edges is Nₑ, and number of loop currents is N₁.

Establishing a sparse mapping matrix M from the loop currents to the edges; the sparse mapping matrix M has dimensions N₁×Nₑ; and a non-zero element of the matrix M is 1 or −1, wherein the element is set to 1 if directions of currents defined on associated edges align with directions of the loop currents, and is set to −1 if the directions are opposite.

Establishing sparse mapping matrices A₁, A₂, A₃ from the edges to the surface elements; the sparse mapping matrices A₁, A₂, A₃ each have dimensions Nₑ×Nₚ; a method for obtaining the sparse mapping matrices A₁, A₂, A₃ specifically comprises: for surface element Sᵢ, obtaining current vectors ρᵢₖ associated with each of the edges; and for surface element Sⱼ, obtaining current vectors ρⱼ₁ associated with each of the edges; k and 1 are indices of the edges on the surface elements Sᵢ and Sⱼ, respectively; if directions of the current vectors ρᵢₖ align with current directions defined on the associated edges, then: A₁(k, i)=ρᵢₖ(x), A₂(k, i)=ρᵢₖ(y), and A₃(k, i)=ρᵢₖ(z); otherwise: A₁(k, i)=−ρᵢₖ(x), A₂(k, i)=−ρᵢₖ(y), and A₃(k, i)=−ρᵢₖ(z); wherein x, y, z denote the x-, y-, and z-components of the current vectors; and if directions of the current vectors ρⱼ₁ align with the current directions defined on the associated edges, then: A₁(1, j)=ρⱼ₁(x), A₂(1, j)=ρⱼ₁(y), and A₃(1, j)=ρⱼ₁(z); otherwise: A₁(1, j)=−ρⱼ₁(x), A₂(1, j)=−ρⱼ₁(y), and A₃(1, j)=−ρⱼ₁(z).

Mapping the loop currents onto the surface elements; and a linear equation for solving the RL parameters by using loop current analysis is further transformed into:

$${Z}_{S} {I}_{l} + M ( {A}_{1} {PA}_{1}^{T} + {A}_{2} {PA}_{2}^{T} + {A}_{3} {PA}_{3}^{T} ) {M}^{T} {I}_{l} = {V}_{l} ;$$

wherein, P denotes a surface element-based scalar potential integral matrix;
M(A₁PIₚ₁+A₂PIₚ₂+A₃PIₚ₃)=V₁; and
wherein,

$${I}_{p 1} = {A}_{1}^{T} {M}^{T} {I}_{l} , {I}_{p 2} = {A}_{2}^{T} {M}^{T} {I}_{l} , {I}_{p 3} = {A}_{3}^{T} {M}^{T} {I}_{l} .$$

Through the above conversion, only the fast multipole method is used to accelerate the matrix-vector multiplication PIₚ₁, PIₚ₂, PIₚ₃; taking triangulation as an example, number of the edges is 1.5 times the number of the surface elements; this can reduce the number of operations using the fast multipole method by 1.5 times; and the fast multipole method itself is proposed for impulse functions, so the new formula directly uses the fast multipole method without any vector decompositions. In addition, direct solutions of the fast multipole method will also be reduced and calculations of integral will be faster after being converted to a scalar potential integral.

Scalar potential integral calculation speed is 9-16 times faster than vector potential integral (the vector potential integral calculation needs to retrieve the edges of each of the two surface elements; if there are two triangle surface elements, number of edge combinations is 9; and if there are rectangular surface elements, number of edge combinations is 16). The number of edges is generally 1.5-2 times the number of the surface elements.

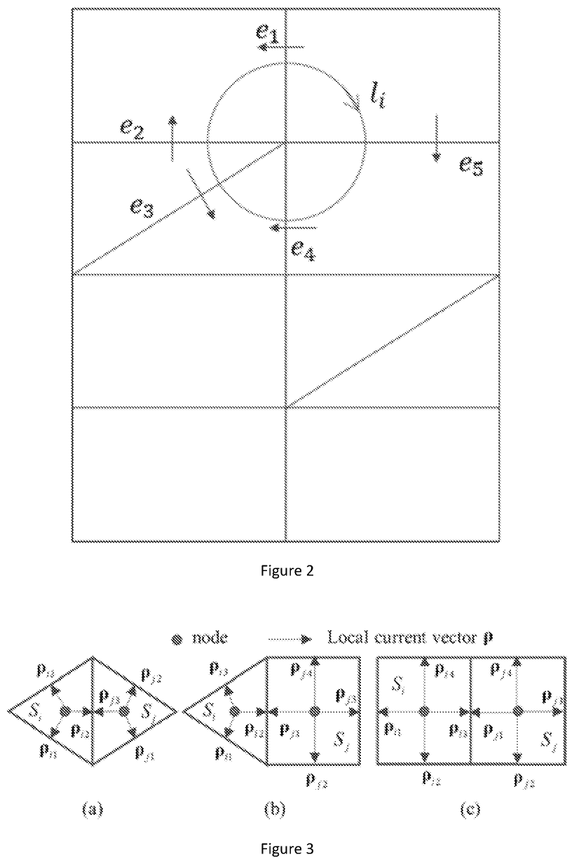

As shown in FIG. 2, the circular arrow indicates a direction of a loop current Iᵢ, and straight arrows indicate directions of the edges e1 to e5; and the loop Iᵢ contains the five edges, and
the directions of e₂, e₄, and e₅ are consistent with the direction of Iᵢ, then

$$M ( {I}_{i} , [ {e}_{2} , {e}_{4} , {e}_{5} ] ) = 1 , , M ( I ∓ , [ {e}_{1} , {e}_{3} ] ) = - 1 .$$

This invention proposes a new CM (centroid-midpoint) basis function to discretize surface currents of a conductor into local currents on the surface elements; as shown in FIG. 3, the basis function connects the centroids of the surface elements and the midpoints of the edges; the fast multipole method shows how to generate these three mapping matrices;

In the prior art, a linear equation for solving RL parameters by loop current analysis are as follows:

$${Z}_{s} {I}_{1} + {Z}_{1} {I}_{1} = {V}_{1}$$

Herein, Z₁ represents a system matrix for calculation of integral of the loop currents, I₁ represents loop current vectors, V₁ represents voltage excitation, and Zₛ represents surface impedance. By applying the matrix M, the equation can be transformed into:

$${Z}_{S} {I}_{1} + M {Z}_{e} {M}^{T} {I}_{1} = {V}_{1}$$

Herein, Zₑ of the present invention represents a system matrix for the calculation of vector bit integration of currents on the edges.

In the traditional way, the integral calculation when the matrix Zₑ is filled is time-consuming, and the FMM (fast multipole method) configuration based on the original formula requires the currents on the edges to be decomposed and the FMM to be used separately, which is complicated to configure. Both direct solution path and precondition filling of the FMM require direct vector potential integral calculation, which is very time-consuming.

Z_{S}I₁ is a sparse matrix-vector multiplication, which does not require to be accelerated by the FMM. Here, only a second part of the equation needs to be accelerated by the FMM. In order to configure the FMM; and the second part of the above equation is converted again into:

$$M ( {A}_{1} {PI}_{p 1} + {A}_{2} {PI}_{p 2} + {A}_{3} {PI}_{p 3} ) = {V}_{1} ;$$

$$Wherein , {I}_{p 1} = {A}_{1}^{T} {M}^{T} {I}_{l} , {I}_{p 2} = {A}_{2}^{T} {M}^{T} {I}_{l} , {I}_{p 3} = {A}_{3}^{T} {M}^{T} {I}_{l}$$

The FMM can be directly applied to PIₚ₁, PIₚ₂, and PIₚ₃. Note that the FMM is applied to this form of matrix-vector multiplication. Currently, the FMM mentioned in the known literature for calculating the RL parameters cannot be directly applied. The FMM is a mature classic algorithm and will not be described in detail in the present invention. The present invention uses the FMM configuration has following benefits:
(1) No need for internal decomposition of the edge currents by directly using the FMM.
(2) Compared to the prior art, processing surface elements saves 1.5-2 times of computing time.
(3) The direct path of FMM involves integral calculation. The present invention converts the vector potential integral into the scalar potential integral, which can save 9-16 times of computing time.

The present invention establishes a preconditioning matrix, wherein only diagonal elements of the P matrix are required. Compared with the traditional edge-based preconditioning matrix (the diagonal of Zₑ), it can also save 9-16 times of computing time.

Beneficial effects: the present invention proposes a method for converting the vector potential integral operation of the RWG basis functions into the scalar potential integral calculation of the impulse functions. Since the impulse functions are built on the surface elements, this new integral calculation method is easier to operate and has a faster calculation speed. Correspondingly, uses of the fast multipole method only need to be based on the surface elements instead of the edges. It is easier to configure the fast multipole method.

The above specific embodiments further illustrate the objectives, technical solutions and beneficial effects of the present invention in detail. It should be understood that the above are only specific implementation methods of the present invention and are not intended to limit the protective scope of the present invention. Any modifications, equivalent substitutions, improvements, etc. made within the spirit and principles of the present invention should be included in the protective scope of the present invention.

1. A configuration method for RL parameter extraction based on a fast multipole method, wherein the configuration method comprises:
meshing a surface of a conductor into hybrid rectangular/triangular surface elements, wherein number of the surface elements is Nₚ, number of edges is Nₑ, and number of loop currents is N₁;
establishing a sparse mapping matrix M from the loop currents to the edges;
establishing sparse mapping matrices A₁, A₂, A₃ from the edges to the surface elements;
discretizing conductor surface current using centroid-midpoint basis functions first proposed herein;
applying the sparse mapping matrices to map the loop currents onto the surface elements;
constructing a preconditioner matrix;
accelerating matrix-vector multiplication by configuring the fast multipole method based on the surface elements; and
post-processing to extract RL parameters.

2. The configuration method based on the fast multipole method according to claim 1, wherein the sparse mapping matrix M has dimensions N₁×Nₑ, and the sparse mapping matrices A₁, A₂, A₃ each have dimensions Nₑ×Nₚ.

3. The configuration method based on the multipole method according to claim 1, wherein a non-zero element of the matrix M is 1 or −1, wherein the element is set to 1 if directions of currents defined on associated edges align with directions of the loop currents, and is set to −1 if the directions are opposite.

4. The configuration method based on the multipole method according to claim 1, wherein the non-zero element in each column of the sparse mapping matrices A₁, A₂, A₃ corresponds to indices of edges belonging to associated surface elements; and values of the matrices are respectively x-, y-, or z-components of difference vectors between midpoint coordinates of the edges and centroid coordinates of the surface elements.

5. The configuration method based on the multipole method according to claim 1, wherein a method for obtaining the sparse mapping matrices A₁, A₂, A₃ specifically comprises:
for surface element Sᵢ, obtaining current vectors ρᵢₖ associated with each of the edges; and for surface element Sⱼ, obtaining current vectors ρⱼ₁ associated with each of the edges;
k and 1 are indices of the edges on the surface elements Sᵢ and Sⱼ, respectively;
if directions of the current vectors ρᵢₖ align with current directions defined on the associated edges, then: A₁(k, i)=ρᵢₖ(x), A₂(k, i)=ρᵢₖ(y), and A₃(k, i)=ρᵢₖ(z);
otherwise: A₁(k, i)=−ρᵢₖ(x), A₂(k, i)=−ρᵢₖ(y), and A₃(k, i)=−ρᵢₖ(z); wherein x, y, z denote the x-, y-, and z-components of the current vectors; and
if directions of the current vectors ρⱼ₁ align with the current directions defined on the associated edges, then: A₁(1, j)=ρⱼ₁(x), A₂(1, j)=ρⱼ₁(y), and A₃(1, j)=ρⱼ₁(z);
otherwise: A₁(1, j)=−ρⱼ₁(x), A₂(1, j)=−ρⱼ₁(y), and A₃(1, j)=−ρⱼ₁(z).

6. The configuration method based on the fast multipole method according to claim 5, wherein based on mapping the loop currents onto the surface elements, a formulation is as follows:
a linear equation for solving the RL parameters by using loop current analysis is further transformed into:
$${Z}_{S} {I}_{l} + M ( {A}_{1} {PA}_{1}^{T} + {A}_{2} {PA}_{2}^{T} + {A}_{3} {PA}_{3}^{T} ) {M}^{T} {I}_{l} = {V}_{l} ;$$
wherein, P denotes a surface element-based scalar potential integral matrix;
M(A₁PIₚ₁+A₂PIₚ₂+A₃PIₚ₃)=V₁; and
wherein,
$${I}_{p 1} = {A}_{1}^{T} {M}^{T} {I}_{l} , {I}_{p 2} = {A}_{2}^{T} {M}^{T} {I}_{l} , {I}_{p 3} = {A}_{3}^{T} {M}^{T} {I}_{l} .$$
